(19) United States
(12) Patent Application Publication
(10) Pub. No.: US 2024/0399715 A1
(43) Pub. Date: Dec. 5, 2024

(54) BASE MATERIAL FOR METAMATERIAL, METAMATERIAL, AND LAMINATE

(71) Applicant: FUJIFILM Corporation, Tokyo (JP)

(72) Inventor: Yasuyuki SASADA, Kanagawa (JP)

(73) Assignee: FUJIFILM Corporation, Tokyo (JP)

(21) Appl. No.: 18/805,552

(22) Filed: Aug. 15, 2024

Related U.S. Application Data
(63) Continuation of application No. PCT/JP2023/003879, filed on Feb. 6, 2023.

(30) Foreign Application Priority Data
Feb. 28, 2022 (JP) 2022-030210

(51) Int. Cl. B32B 15/09; B32B 15/20; B32B 27/08; B32B 27/20; B32B 27/32; B32B 27/36

(52) U.S. Cl. CPC B32B 15/09; B32B 15/20; B32B 27/08; B32B 27/20; B32B 27/325; B32B 27/36; B32B 2307/202; B32B 2307/204; B32B 2307/206; B32B 2307/30; B32B 2307/538; B32B 2307/7246; B32B 2307/7376

(57) ABSTRACT

Provided are a base material for a metamaterial, in which a glass transition temperature is 160° C. or higher and a surface roughness Ra of at least one surface is 300 nm or less; and a metamaterial and a laminate including the base material for a metamaterial.

### CROSS-REFERENCE TO RELATED APPLICATIONS

This application is a continuation application of International Application No. PCT/JP2023/003879, filed Feb. 6, 2023, the disclosure of which is incorporated herein by reference in its entirety. Further, this application claims priority from Japanese Patent Application No. 2022-030210, filed Feb. 28, 2022, the disclosure of which is incorporated herein by reference in its entirety.

### BACKGROUND OF THE INVENTION

### 1. Field of the Invention

The present disclosure relates to a base material for a metamaterial, a metamaterial, and a laminate.

### 2. Description of the Related Art

In recent years, it has been studied to apply a metamaterial including a base material and a pattern which is composed of a conductive material or the like and is provided on a surface of the base material to an optical element for electromagnetic waves having a frequency of 0.1 THz to 10 THz (wavelength: 30 μm to 3,000 μm) (hereinafter, also referred to as electromagnetic waves in a terahertz band).

For example, JP2021-114647A discloses a metamaterial including a metasurface base material and a pattern of a metal film, provided on a surface of the metasurface base material.

### SUMMARY OF THE INVENTION

Here, the above-described pattern included in the metamaterial functions as a resonator with respect to the electromagnetic waves in a terahertz band. Since a portion that functions as the resonator with respect to the electromagnetic waves in a terahertz band is left up to a portion of approximately 0.5 μm from a surface of the pattern, it is assumed that the thickness of the pattern is to be reduced from the viewpoint of cost reduction and the like in the future development.

A pattern having a small thickness is likely to be formed on the surface of the base material by a method such as a sputtering method and a vapor deposition method, and smoothness of the pattern surface is lowered depending on smoothness of the surface of the base material.

Since the smoothness of the pattern surface is reduced, the path through which the current flows is substantially lengthened, so that a transmission loss which may occur tends to increase. In particular, electromagnetic waves having a high frequency, such as electromagnetic waves in a terahertz band, tend to be affected by the decrease in transmission loss due to the smoothness of the pattern surface because the electromagnetic waves remain in a portion of approximately 0.5 μm in the thickness direction from the pattern surface.

In addition, as the base material, a cyclic olefin resin (hereinafter, also referred to as COP) film has been used in the related art. The COP film has excellent smoothness, but has low heat resistance, and a surface thereof is roughened in a pattern formation using a sputtering method or the like, which may impair the smoothness of the formed pattern.

An object to be achieved by an embodiment of the present disclosure is to provide a base material for a metamaterial, which has excellent heat resistance and smoothness and can improve smoothness of a pattern to be formed, a metamaterial, and a laminate.

Specific methods for achieving the object are as follows.

<1> A base material for a metamaterial,
in which a glass transition temperature is 160° C. or higher, and
a surface roughness Ra of at least one surface is 300 nm or less.

<2> The base material for a metamaterial according to <1>,
in which a dielectric loss tangent is 0.01 or less.

<3> The base material for a metamaterial according to <1> or <2>,
in which the base material for a metamaterial contains at least one selected from the group consisting of a fluorine-based polymer and a liquid crystal polymer.

<4> A metamaterial comprising:
the base material for a metamaterial according to any one of <1> to <3>; and
a pattern provided on a surface of the base material for a metamaterial, the surface having a surface roughness Ra of 300 nm or less,
in which the pattern is composed of at least one of a conductive material or a material which transits from an insulator to a conductor.

<5> The metamaterial according to <4>,
in which a thickness of the pattern is less than 5 μm.

<6> The metamaterial according to <4> or <5>,
in which the pattern includes a plurality of structural bodies, and
the structural bodies are a split-ring resonator.

<7> The metamaterial according to any one of <4> to <6>,
in which the pattern is composed of the conductive material, and
the conductive material includes a metal.

<8> A laminate comprising:
the metamaterial according to any one of <4> to <7>; and
an organic film provided on a surface of the metamaterial on a pattern side.

<9> The laminate according to <8>,
in which a moisture permeability of the organic film in an environment of a temperature of 40° C. and a relative humidity of 90% is 3,000 g/(m²·24 hours) or less.

<10> The laminate according to <8> or <9>,
in which the organic film contains an ultraviolet absorber.

According to the embodiment of the present disclosure, it is possible to provide a base material for a metamaterial, which has excellent heat resistance and smoothness and can improve smoothness of a pattern to be formed, a metamaterial, and a laminate.

### BRIEF DESCRIPTION OF THE DRAWINGS

FIG. 1 is a perspective view showing an embodiment of a metamaterial according to the present disclosure.

### DESCRIPTION OF THE PREFERRED EMBODIMENTS

In the present disclosure, the numerical ranges shown using “to” include the numerical values described before and after “to” as the minimum value and the maximum value.

In a numerical range described in a stepwise manner in the present disclosure, an upper limit or a lower limit described in one numerical range may be replaced with an upper limit or a lower limit in another numerical range described in a stepwise manner. Further, in a numerical range described in the present disclosure, an upper limit or a lower limit described in the numerical range may be replaced with a value described in an example.

In the present disclosure, each component may contain a plurality of types of corresponding substances.

In the present disclosure, a term “layer” or “film” includes not only a case where the layer or the film is formed over the entire region but also a case where the layer or the film is formed only in part of the region.

In the present disclosure, the term “step” includes not only an independent step but also a step that cannot be clearly distinguished from other steps, as long as the intended purpose of the step is achieved.

In the present disclosure, the term “metamaterial” refers to a member which is composed of a conductive material or the like and has a pattern that functions as a resonator with respect to electromagnetic waves.

The metamaterial preferably has a pattern serving as a resonator with respect to electromagnetic waves having a frequency of 0.01 THz to 10 THz (wavelength: 30 μm to 30,000 μm), and more preferably has a pattern serving as a resonator with respect to electromagnetic waves having a frequency of 0.1 THz to 10 THz (wavelength: 30 μm to 3,000 μm).

In the present disclosure, a measurement of a moisture permeability is carried out under conditions of a temperature of 40° C., a relative humidity of 90%, and 24 hours of standing, in conformity with the method described in JIS Z 0208 (1976).

In the present disclosure, a weight-average molecular weight (Mw) is a molecular weight converted using polystyrene as a standard substance by performing detection with a gel permeation chromatography (GPC) analysis apparatus using TSKgel SuperHM-H (trade name, manufactured by Tosoh Corporation) column, a solvent of pentafluorophenol (PFP) and chloroform at a mass ratio of 1:2, and a differential refractometer, unless otherwise specified.

In the present disclosure, “(meth)acrylic” is a concept including both acrylic and methacrylic.

In the present disclosure, “solid content” means components forming a layer formed of a composition or the like, and in a case where the composition or the like contains a solvent (an organic solvent, water, or the like), it means all components excluding the solvent. In addition, a liquid component is also regarded as the solid content in a case where the component is a component which forms the layer.

In the present disclosure, in a case where an embodiment is described with reference to the drawing, the configuration of the embodiment is not limited to the configuration shown in the drawing. In addition, sizes of members in each drawing are conceptual, and a relative relationship between the sizes of the members is not limited thereto.

### [Base Material for Metamaterial]

The base material for a metamaterial (hereinafter, also referred to as a base material) according to the present disclosure has a glass transition temperature of 160° C. or higher and a surface roughness Ra of at least one surface of 300 nm or less.

From the viewpoint of heat resistance, the glass transition temperature of the base material is preferably 165° C. to 300° C., more preferably 170° C. to 250° C., and still more preferably 175° C. to 230° C.

The glass transition temperature of the base material can be adjusted by changing a material to be contained in the base material, or the like.

In the present disclosure, the glass transition temperature of the base material is measured as follows.

The base material piece is enclosed in a measuring pan, and using a differential scanning calorimeter, the glass transition temperature is obtained from a thermogram obtained by raising the temperature at a rate of 20° C./min, in which the baseline and the intersection temperature of the tangent line at the inflection point are obtained.

As the differential scanning calorimeter, DSC6200 manufactured by Seiko Instruments Inc. or similar apparatus can be used.

In a case where the base material has two or more glass transition temperatures, the condition of “the glass transition temperature of the base material is 160° C. or higher” is satisfied in a case where the smaller glass transition temperature is 160° C. or higher.

From the viewpoint of smoothness of the pattern formed on the surface of the base material, the surface roughness Ra of the base material for a metamaterial is preferably 250 nm or less, more preferably 100 nm or less, still more preferably 50 nm or less, particularly preferably 30 nm or less, and most preferably 10 nm or less. The lower limit of the surface roughness Ra is not particularly limited, and may be 0 nm.

The surface roughness Ra of the base material can be adjusted by changing a material to be contained in the base material, a manufacturing method of the base material, or the like.

Examples of a film forming method of the base material include a method of manufacturing the base material by heating and melting a composition containing the above-described resin and the like, extruding the composition into a film, and cooling the film with a chill roll or the like; and a method of manufacturing the base material by dissolving or dispersing a composition containing the above-described resin and the like in a solvent, forming a film by casting, coating, or the like, and drying the film. Here, in order to improve the smoothness of the support surface side, it is preferable to use a support having high smoothness, such as a chill roll, a casting support, and a coating support. In addition, from the viewpoint of improving the smoothness, a film forming method of casting or applying a solution is preferable. Furthermore, in order to improve the smoothness of the surface forming the metamaterial, it is also effective to coat and dry the surface of the film formed by melting or the film formed by a solution using a reverse gravure coater or the like. In addition, in order to improve the smoothness, it is also effective to stretch the film to be formed or to adjust the tension applied to the film in the drying or heat treatment step.

The surface roughness Ra of the base material is obtained as follows.

First, a cross-sectional sample of the base material is cut out using a microtome. A curve of an interface shape of the cut out cross-sectional sample and an average line of the curve of the interface shape are created, and the surface roughness Ra is obtained from these. In a case where the base material is included in a metamaterial, a laminate, or the like, which will be described later, a cross-sectional sample of the metamaterial or the like is used.

For the above-described measurement of the surface roughness Ra, a non-contact surface and cross-sectional shape measurement system VertScan (Mitsubishi Chemical System Co., Ltd.) or similar apparatus can be used.

From the viewpoint of electrical characteristics, a dielectric loss tangent of the base material is preferably 0.01 or less, more preferably 0.0005 to 0.007, still more preferably 0.001 to 0.006, and particularly preferably 0.001 to 0.005.

The dielectric loss tangent of the base material can be adjusted by changing a material to be contained in the base material, or the like.

In the present disclosure, the dielectric loss tangent of the base material is measured by the following terahertz time-domain spectroscopy (THz-TDS).

First, the base material is cut into a test piece having a size of 100 mm×100 mm.

Next, an optical system for transmission-type terahertz spectroscopy is produced, and a dielectric loss tangent of the test piece is measured from a change in time waveform of the electric field (frequency: 1 THz) before and after insertion of the test piece in an environment of a temperature of 25° C. and a humidity of 10% RH.

In a case where the pattern described later is formed on the surface of the base material, the above-described measurement of the dielectric loss tangent is carried out using a base material etched with a solution such as iron chloride.

### (Resin)

The material constituting the base material is not particularly limited, but from the viewpoint of handleability and the like, a resin is preferable.

Examples of the resin which can be contained in the base material include thermoplastic resins such as a liquid crystal polymer, a fluorine-based polymer, a polymerized substance of a compound which has a cyclic aliphatic hydrocarbon group and a group having an ethylenically unsaturated bond, polyether ether ketone, polyolefin, polyamide, polyester, polyphenylene sulfide, aromatic polyether ketone, polycarbonate, polyarylate, polyethersulfone, polyphenylene ether and a modified product thereof, and polyetherimide; elastomers such as a copolymer of glycidyl methacrylate and polyethylene; and thermosetting resins such as a phenol resin, an epoxy resin, a polyimide resin, and a cyanate resin.

Among these, from the viewpoint of dielectric loss tangent, adhesiveness with the pattern, and heat resistance, at least one selected from the group consisting of a liquid crystal polymer, a fluorine-based polymer, a polymerized substance of a compound which has a cyclic aliphatic hydrocarbon group and a group having an ethylenically unsaturated bond, polyphenylene ether, aromatic polyether ketone, and an epoxy resin is preferable, and at least one selected from the group consisting of a liquid crystal polymer and a fluorine-based polymer is more preferable.

From the viewpoint of adhesiveness with the pattern and mechanical strength, a liquid crystal polymer is preferable, and from the viewpoint of heat resistance and dielectric loss tangent, a polymerized substance of a compound which has a cyclic aliphatic hydrocarbon group and a group having an ethylenically unsaturated bond, a polyarylate, a polyethersulfone, or a fluorine-based polymer is preferable.

The liquid crystal polymer may be a thermotropic liquid crystal polymer which exhibits liquid crystallinity in a molten state, or may be a lyotropic liquid crystal polymer which exhibits liquid crystallinity in a solution state. Further, in a case where the liquid crystal polymer is a thermotropic liquid crystal polymer, the liquid crystal polymer is preferably a liquid crystal polymer which is molten at a temperature of 450° C. or lower.

Examples of the liquid crystal polymer include a liquid crystal polyester, a liquid crystal polyester amide in which an amide bond is introduced into the liquid crystal polyester, a liquid crystal polyester ether in which an ether bond is introduced into the liquid crystal polyester, and a liquid crystal polyester carbonate in which a carbonate bond is introduced into the liquid crystal polyester.

In addition, as the liquid crystal polymer, from the viewpoint of liquid crystallinity and thermal expansion coefficient, a polymer having an aromatic ring is preferable, and an aromatic polyester or an aromatic polyester amide is more preferable.

Further, the liquid crystal polymer may be a polymer in which an imide bond, a carbodiimide bond, a bond derived from an isocyanate, such as an isocyanurate bond, or the like is further introduced into the aromatic polyester or the aromatic polyester amide.

Further, it is preferable that the liquid crystal polymer is a wholly aromatic liquid crystal polymer formed of only an aromatic compound as a raw material monomer.

Examples of the liquid crystal polymer include the following liquid crystal polymers.
1) a liquid crystal polymer obtained by polycondensing (i) an aromatic hydroxycarboxylic acid, (ii) an aromatic dicarboxylic acid, and (iii) at least one compound selected from the group consisting of an aromatic diol, an aromatic hydroxyamine, and an aromatic diamine;
2) a liquid crystal polymer obtained by polycondensing a plurality of types of aromatic hydroxycarboxylic acids;
3) a liquid crystal polymer obtained by polycondensing (i) an aromatic dicarboxylic acid and (ii) at least one compound selected from the group consisting of an aromatic diol, an aromatic hydroxyamine, and an aromatic diamine;
4) a liquid crystal polymer obtained by polycondensing (i) polyester such as polyethylene terephthalate and (ii) an aromatic hydroxycarboxylic acid.

Here, the aromatic hydroxycarboxylic acid, the aromatic dicarboxylic acid, the aromatic diol, the aromatic hydroxyamine, and the aromatic diamine may be each independently replaced with a polycondensable derivative.

For example, the aromatic hydroxycarboxylic acid and the aromatic dicarboxylic acid can be replaced with aromatic hydroxycarboxylic acid ester and aromatic dicarboxylic acid ester, by converting a carboxy group into an alkoxycarbonyl group or an aryloxycarbonyl group.

The aromatic hydroxycarboxylic acid and the aromatic dicarboxylic acid can be replaced with aromatic hydroxycarboxylic acid halide and aromatic dicarboxylic acid halide, by converting a carboxy group into a haloformyl group.

The aromatic hydroxycarboxylic acid and the aromatic dicarboxylic acid can be replaced with aromatic hydroxycarboxylic acid anhydride and aromatic dicarboxylic acid anhydride, by converting a carboxy group into an acyloxycarbonyl group.

Examples of a polymerizable derivative of a compound having a hydroxy group, such as an aromatic hydroxycarboxylic acid, an aromatic diol, and an aromatic hydroxyamine, include a derivative (acylated product) obtained by acylating a hydroxy group and converting the acylated group into an acyloxy group.

For example, the aromatic hydroxycarboxylic acid, the aromatic diol, and the aromatic hydroxyamine can be each replaced with an acylated product by acylating a hydroxy group and converting the acylated group into an acyloxy group.

Examples of a polymerizable derivative of a compound having an amino group, such as an aromatic hydroxyamine or an aromatic diamine, include a derivative (acylated product) obtained by acylating an amino group and converting the acylated group to an acylamino group.

For example, the aromatic hydroxyamine and the aromatic diamine can be each replaced with an acylated product by acylating an amino group and converting the acylated group into an acylamino group.

From the viewpoint of liquid crystallinity, dielectric loss tangent, and adhesiveness with the pattern, the liquid crystal polymer preferably has a constitutional unit represented by any of Formulae (1) to (3) (hereinafter, a constitutional unit represented by Formula (1) or the like may be referred to as a constitutional unit (1) or the like), more preferably has a constitutional unit represented by Formula (1), and particularly preferably has a constitutional unit represented by Formula (1), a constitutional unit represented by Formula (2), and a constitutional unit represented by Formula (3).

—O—Ar¹—CO— Formula (1)

—CO—Ar²—CO— Formula (2)

—X—Ar³—Y— Formula (3)

In Formulae (1) to (3), Ar¹ represents a phenylene group, a naphthylene group, or a biphenylylene group, Ar² and Ar³ each independently represent a phenylene group, a naphthylene group, a biphenylylene group, or a group represented by Formula (4), X and Y each independently represent an oxygen atom or an imino group, and hydrogen atoms in Ar¹ to Ar³ may be each independently substituted with a halogen atom, an alkyl group, or an aryl group.

—Ar⁴—Z—Ar⁵— Formula (4)

In Formula (4), Ar⁴ and Ar⁵ each independently represent a phenylene group or a naphthylene group, and Z represents an oxygen atom, a sulfur atom, a carbonyl group, a sulfonyl group, or an alkylene group.

Examples of the halogen atom include a fluorine atom, a chlorine atom, a bromine atom, and an iodine atom.

Examples of the alkyl group include a methyl group, an ethyl group, an n-propyl group, an isopropyl group, an n-butyl group, an isobutyl group, an s-butyl group, a t-butyl group, an n-hexyl group, a 2-ethylhexyl group, an n-octyl group, and an n-decyl group. The number of carbon atoms in the alkyl group is preferably 1 to 10.

Examples of the aryl group include a phenyl group, an o-tolyl group, an m-tolyl group, a p-tolyl group, a 1-naphthyl group, and a 2-naphthyl group. The number of carbon atoms in the aryl group is preferably 6 to 20.

In a case where the hydrogen atom is substituted with any of these groups, the number of each of substitutions in Ar¹, Ar², and Ar³ independently is preferably 2 or less and more preferably 1.

Examples of the alkylene group include a methylene group, a 1,1-ethanediyl group, a 1-methyl-1,1-ethanediyl group, a 1,1-butanediyl group, and a 2-ethyl-1,1-hexanediyl group. The number of carbon atoms in the alkylene group is preferably 1 to 10.

The constitutional unit (1) is a constitutional unit derived from an aromatic hydroxycarboxylic acid.

As the constitutional unit (1), an aspect in which Ar¹ represents a p-phenylene group (constitutional unit derived from p-hydroxybenzoic acid), an aspect in which Ar¹ represents a 2,6-naphthylene group (constitutional unit derived from 6-hydroxy-2-naphthoic acid), or an aspect in which Ar¹ represents a 4,4′-biphenylylene group (constitutional unit derived from 4′-hydroxy-4-biphenylcarboxylic acid) is preferable.

The constitutional unit (2) is a constitutional unit derived from an aromatic dicarboxylic acid.

As the constitutional unit (2), an aspect in which Ar² represents a p-phenylene group (constitutional unit derived from terephthalic acid), an aspect in which Ar² represents an m-phenylene group (constitutional unit derived from isophthalic acid), an aspect in which Ar² represents a 2,6-naphthylene group (constitutional unit derived from 2,6-naphthalenedicarboxylic acid), or an aspect in which Ar² represents a diphenylether-4,4′-diyl group (constitutional unit derived from diphenylether-4,4′-dicarboxylic acid) is preferable.

The constitutional unit (3) is a constitutional unit derived from an aromatic diol, an aromatic hydroxyamine, or an aromatic diamine.

As the constitutional unit (3), an aspect in which Ar³ represents a p-phenylene group (constitutional unit derived from hydroquinone, p-aminophenol, or p-phenylenediamine), an aspect in which Ar³ represents an m-phenylene group (constitutional unit derived from isophthalic acid), or an aspect in which Ar³ represents a 4,4′-biphenylylene group (constitutional unit derived from 4,4′-dihydroxybiphenyl, 4-amino-4′-hydroxybiphenyl, or 4,4′-diaminobiphenyl) is preferable.

A content of the constitutional unit (1) is preferably 30% by mole or more, more preferably 30% to 80% by mole, still more preferably 30% to 60% by mole, and particularly preferably 30% to 40% by mole with respect to the total amount of all constitutional units (a value obtained by dividing the mass of each constitutional unit (also referred to as “monomer unit”) constituting the liquid crystal polymer by the formula weight of each constitutional unit to calculate an amount (mole) equivalent to the substance amount of each constitutional unit and adding up the amounts).

A content of the constitutional unit (2) is preferably 35% by mole or less, more preferably 10% by mole to 35% by mole, still more preferably 20% by mole to 35% by mole, and particularly preferably 30% by mole to 35% by mole with respect to the total amount of all constitutional units.

A content of the constitutional unit (3) is preferably 35% by mole or less, more preferably 10% by mole to 35% by mole, still more preferably 20% by mole to 35% by mole, and particularly preferably 30% by mole to 35% by mole with respect to the total amount of all constitutional units.

The heat resistance, the strength, and the rigidity are likely to be improved as the content of the constitutional unit (1) increases, but the solubility in a solvent is likely to be decreased in a case where the content thereof is extremely large.

A proportion of the content of the constitutional unit (2) to the content of the constitutional unit (3) is expressed as [content of constitutional unit (2)]/[content of constitutional unit (3)](mol/mol), and is preferably 0.9/1 to 1/0.9, more preferably 0.95/1 to 1/0.95, and still more preferably 0.98/1 to 1/0.98.

The liquid crystal polymer may have two or more kinds of each of the constitutional units (1) to (3) independently. In addition, the liquid crystal polymer may have a constitutional unit other than the constitutional units (1) to (3), but the content thereof is preferably 10% by mole or less and more preferably 5% by mole or less with respect to the total amount of all the constitutional units.

From the viewpoint of solubility in a solvent, the liquid crystal polymer preferably has, as the constitutional unit (3), a constitutional unit (3) in which at least one of X or Y is an imino group, that is, preferably has as the constitutional unit (3), at least one of a constitutional unit derived from an aromatic hydroxyamine or a constitutional unit derived from an aromatic diamine, and it is more preferable to have only a constitutional unit (3) in which at least one of X or Y is an imino group.

It is preferable that the liquid crystal polymer is produced by melt-polymerizing raw material monomers corresponding to the constitutional units constituting the liquid crystal polymer. The melt polymerization may be carried out in the presence of a catalyst. Examples of the catalyst include metal compounds such as magnesium acetate, stannous acetate, tetrabutyl titanate, lead acetate, sodium acetate, potassium acetate, and antimony trioxide, and nitrogen-containing heterocyclic compounds such as 4-(dimethylamino)pyridine and 1-methylimidazole; and preferred examples thereof include nitrogen-containing heterocyclic compounds. The melt polymerization may be further carried out by solid phase polymerization as necessary.

In addition, a weight-average molecular weight of the liquid crystal polymer is preferably 1,000,000 or less, more preferably 3,000 to 300,000, still more preferably 5,000 to 100,000, and particularly preferably 5,000 to 30,000. In a case where the weight-average molecular weight of the liquid crystal polymer is within the above-described range, the base material is excellent in thermal conductivity, heat resistance, strength, and rigidity in the thickness direction.

Examples of the fluorine-based polymer include polytetrafluoroethylene, polychlorotrifluoroethylene, polyvinylidene fluoride, polyvinyl fluoride, a perfluoroalkoxy fluororesin, an ethylene tetrafluoride/propylene hexafluoride copolymer, an ethylene/ethylene tetrafluoride copolymer, and an ethylene/chlorotrifluoroethylene copolymer.

Among these, polytetrafluoroethylene is preferable.

In addition, examples of the fluorine-based polymer include a fluorinated α-olefin monomer, that is, an α-olefin monomer containing at least one fluorine atom; and a homopolymer and a copolymer optionally containing a constitutional unit derived from a non-fluorinated ethylenically unsaturated monomer reactive to the fluorinated α-olefin monomer.

Examples of the fluorinated α-olefin monomer include CF₂═CF₂, CHF═CF₂, CH₂—CF₂, CHCl═CHF, CClF—CF₂, CCl₂—CF₂, CClF—CClF, CHF═CCl₂, CH₂═CClF, CCl₂═CClF, CF₃CF—CF₂, CF₃CF—CHF, CF₃CH═CF₂, CF₃CH═CH₂, CHF₂CH═CHF, CF₃CF═CF₂, and perfluoro (alkyl having 2 to 8 carbon atoms) vinyl ether (for example, perfluoromethyl vinyl ether, perfluoropropyl vinyl ether, and perfluorooctyl vinyl ether). Among these, at least one monomer selected from the group consisting of tetrafluoroethylene (CF₂═CF₂), chlorotrifluoroethylene (CClF═CF₂), (perfluorobutyl)ethylene, vinylidene fluoride (CH₂═CF₂), and hexafluoropropylene (CF₂═CFCF₃) is preferable.

Examples of the non-fluorinated ethylenically unsaturated monomer include ethylene, propylene, butene, and an ethylenically unsaturated aromatic monomer (for example, styrene and α-methylstyrene).

The fluorinated α-olefin monomer may be used alone or in combination of two or more thereof.

In addition, the non-fluorinated ethylenically unsaturated monomer may be used alone or in combination of two or more thereof.

Examples of the fluorine-based polymer include poly(chlorotrifluoroethylene) (PCTFE), poly(chlorotrifluoroethylene-propylene), poly(ethylene-tetrafluoroethylene) (ETFE), poly(ethylene-chlorotrifluoroethylene) (ECTFE), poly(hexafluoropropylene), poly(tetrafluoroethylene) (PTFE), poly(tetrafluoroethylene-ethylene-propylene), poly(tetrafluoroethylene-hexafluoropropylene) (also referred to as a fluorinated ethylene-propylene copolymer (FEP)), poly(tetrafluoroethylene-propylene) (also referred to as a fluoroelastomer (FEPM)), poly(tetrafluoroethylene-perfluoropropylene vinyl ether), a copolymer having a tetrafluoroethylene main chain and a fully fluorinated alkoxy side chain (perfluoroalkoxy polymer; also referred to as a poly(tetrafluoroethylene-perfluoroalkyl vinyl ether) (PFA)) (for example, poly(tetrafluoroethylene-erfluoropropylene propyl vinyl ether)), polyvinyl fluoride (PVF), fluoride polyvinylidene (PVDF), poly(vinylidenc fluoride-chlorotrifluoroethylene), perfluoropolyether, perfluorosulfonic acid, and perfluoropolyoxctane.

The fluorine-based polymer may be used alone or in combination of two or more thereof.

The fluorine-based polymer is preferably at least one of FEP, PFA, ETFE, or PTFE. These may have fibril-forming properties or non-fibril-forming properties. The FEP is available from Du Pont as the trade name of TEFLON (registered trademark) FEP or from DAIKIN INDUSTRIES, LTD. as the trade name of NEOFLON FEP; and the PFA is available from DAIKIN INDUSTRIES, LTD. as the trade name of NEOFLON PFA, from Du Pont as the trade name of TEFLON (registered trademark) PFA, or from Solvay Solexis as the trade name of HYFLON PFA.

The fluorine-based polymer preferably includes PTFE. The PTFE can be included as a PTFE homopolymer, a partially modified PTFE homopolymer, or a combination including one or both of these. The partially modified PTFE homopolymer preferably contains a constitutional unit derived from a comonomer other than tetrafluoroethylene in an amount of less than 1% by mass based on the total mass of the polymer.

The fluorine-based polymer may be a crosslinkable fluoropolymer having a crosslinkable group. The crosslinkable fluoropolymer can be crosslinked by a known crosslinking method in the related art. One of the representative crosslinkable fluoropolymers is a fluoropolymer having a (meth)acryloxy group. For example, the crosslinkable fluoropolymer can be represented by Formula:

H₂C═CR′COO—(CH₂)ₙ—R—(CH₂)ₙ—OOCR′═CH₂
in the formula, R is a fluorine-based oligomer chain having two or more constitutional units derived from the fluorinated α-olefin monomer or the non-fluorinated monoethylenically unsaturated monomer, R′ is H or —CH₃, and n is 1 to 4. R may be a fluorine-based oligomer chain having a constitutional unit derived from tetrafluoroethylene.

In order to initiate a radical crosslinking reaction through the (meth)acryloxy group in the fluorine-based polymer, by exposing the fluoropolymer having a (meth)acryloxy group to a free radical source, a crosslinked fluoropolymer network can be formed. The free radical source is not particularly limited, and suitable examples thereof include a photoradical polymerization initiator and an organic peroxide. Appropriate photoradical polymerization initiators and organic peroxides are well known in the art. The crosslinkable fluoropolymer is commercially available, and examples thereof include Viton B manufactured by Du Pont.

Examples of the polymerized substance of a compound which has a cyclic aliphatic hydrocarbon group and a group having an ethylenically unsaturated bond include thermoplastic resins having a constitutional unit formed from a monomer having a cyclic olefin such as norbornene and a polycyclic norbornene-based monomer, which is also referred to as a thermoplastic cyclic olefin-based resin.

The polymerized substance of a compound which has a cyclic aliphatic hydrocarbon group and a group having an ethylenically unsaturated bond may be a ring-opened polymer of the above-described cyclic olefin, a hydrogenated product of a ring-opened copolymer using two or more cyclic olefins, or an addition polymer of a cyclic olefin and a linear olefin or aromatic compound having an ethylenically unsaturated bond such as a vinyl group. In addition, a polar group may be introduced into the polymerized substance of a compound which has a cyclic aliphatic hydrocarbon group and a group having an ethylenically unsaturated bond.

The polymerized substance of a compound which has a cyclic aliphatic hydrocarbon group and a group having an ethylenically unsaturated bond may be used alone or in combination of two or more thereof.

A ring structure of the cyclic aliphatic hydrocarbon group may be a single ring, a fused ring in which two or more rings are fused, or a crosslinked ring.

Examples of the ring structure of the cyclic aliphatic hydrocarbon group include a cyclopentane ring, a cyclohexane ring, a cyclooctane ring, an isophorone ring, a norbornane ring, and a dicyclopentane ring.

The compound which has a cyclic aliphatic hydrocarbon group and a group having an ethylenically unsaturated bond may be a monofunctional ethylenically unsaturated compound or a polyfunctional ethylenically unsaturated compound.

The number of cyclic aliphatic hydrocarbon groups in the compound which has a cyclic aliphatic hydrocarbon group and a group having an ethylenically unsaturated bond may be 1 or more, and may be 2 or more.

It is sufficient that the polymerized substance of a compound which has a cyclic aliphatic hydrocarbon group and a group having an ethylenically unsaturated bond is a polymer obtained by polymerizing at least one compound which has a cyclic aliphatic hydrocarbon group and a group having an ethylenically unsaturated bond, and it may be a polymerized substance of two or more kinds of the compound which has a cyclic aliphatic hydrocarbon group and a group having an ethylenically unsaturated bond or a copolymer with other ethylenically unsaturated compounds having no cyclic aliphatic hydrocarbon group.

In addition, the polymerized substance of a compound which has a cyclic aliphatic hydrocarbon group and a group having an ethylenically unsaturated bond is preferably a cycloolefin polymer.

In the polyphenylene ether, from the viewpoint of dielectric loss tangent and heat resistance, the average number of molecular terminal phenolic hydroxyl groups per molecule (the number of terminal hydroxyl groups) is preferably 1 to 5 and more preferably 1.5 to 3.

The number of hydroxyl groups or the number of phenolic hydroxyl groups in the polyphenylene ether can be found, for example, from a standard value of a product of the polyphenylene ether. In addition, examples of the number of terminal hydroxyl groups or the number of terminal phenolic hydroxyl groups include a numerical value representing an average value of hydroxyl groups or phenolic hydroxyl groups per molecule of all polyphenylene ethers present in 1 mol of the polyphenylene ether.

The polyphenylene ether may be used alone or in combination of two or more thereof.

Examples of the polyphenylene ether include a polyphenylene ether including 2,6-dimethylphenol and at least one of bifunctional phenol or trifunctional phenol, and a compound mainly including the polyphenylene ether, such as poly(2,6-dimethyl-1,4-phenylene oxide). More specifically, for example, a compound having a structure represented by Formula (PPE) is preferable.

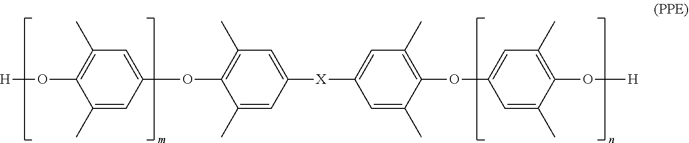

In Formula (PPE), X represents an alkylene group having 1 to 3 carbon atoms or a single bond, m represents an integer of 0 to 20, n represents an integer of 0 to 20, and the sum of m and n represents an integer of 1 to 30.

Examples of the alkylene group in X described above include a dimethylmethylene group.

The aromatic polyether ketone is not particularly limited, and a known aromatic polyether ketone can be used.

The aromatic polyether ketone is preferably a polyether ether ketone.

The polyether ether ketone is one type of the aromatic polyether ketone, and is a polymer in which bonds are arranged in the order of an ether bond, an ether bond, and a carbonyl bond (ketone). It is preferable that the bonds are linked to each other by a divalent aromatic group.

The aromatic polyether ketone may be used alone or in combination of two or more thereof.

Examples of the aromatic polyether ketone include polyether ether ketone (PEEK) having a chemical structure represented by Formula (P1), polyether ketone (PEK) having a chemical structure represented by Formula (P2), polyether ketone ketone (PEKK) having a chemical structure represented by Formula (P3), polyether ether ketone ketone (PEEKK) having a chemical structure represented by Formula (P4), and polyether ketone ether ketone ketone (PEKEKK) having a chemical structure represented by Formula (P5).

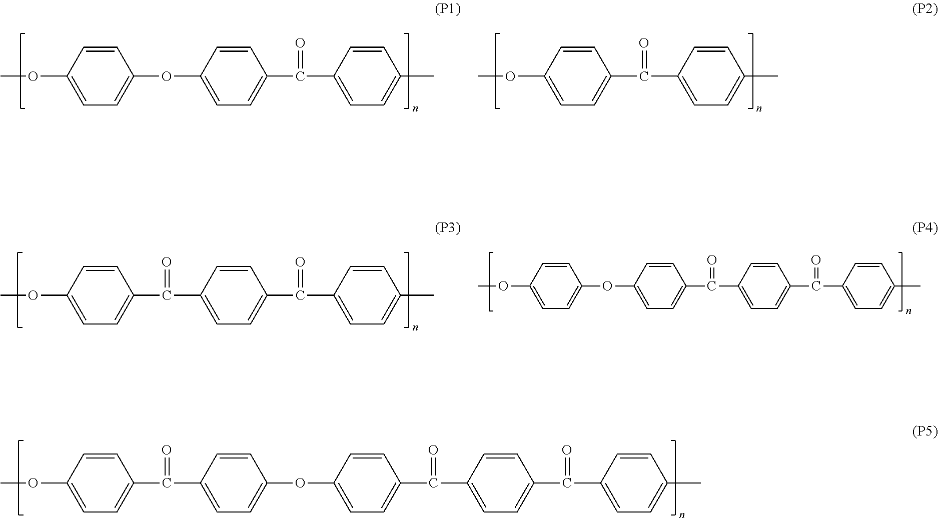

From the viewpoint of mechanical properties, each n of Formulae (P1) to (P5) is preferably 10 or more and more preferably 20 or more. On the other hand, from the viewpoint that the aromatic polyether ketone can be easily produced, n is preferably 5,000 or less and more preferably 1,000 or less. That is, n is preferably 10 to 5,000 and more preferably 20 to 1,000.

A content of the resin with respect to the total mass of the base material is not particularly limited, but is preferably 50% by mass or more, more preferably 70% by mass or more, and still more preferably 90% by mass or more. The upper limit of the content of the resin is not particularly limited, and may be 100% by mass.

### (Compound Having Functional Group)

The base material may contain a compound having a functional group.

From the viewpoint of adhesiveness with the pattern, the functional group is preferably at least one group selected from the group consisting of a covalent-bondable group, an ion-bondable group, a hydrogen-bondable group, a dipole-interactable group, and a curing reactive group with at least one of the conductive material or the material which transits from an insulator to a conductor, constituting the pattern. In addition, depending on the material constituting the base material, the compound having a functional group can also form the above-described bond or the like with the material constituting the base material.

The compound having a functional group may be a low-molecular-weight compound or a high-molecular-weight compound.

From the viewpoint of dielectric loss tangent of the base material, the compound having a functional group is preferably a low-molecular-weight compound, and from the viewpoint of heat resistance and mechanical strength of the base material, it is preferably a high-molecular-weight compound.

It is sufficient that the number of functional groups in the compound having a functional group is 1 or more, and it may be 2 or more. However, the number of functional groups in the compound having a functional group is preferably 2 or more, and from the viewpoint of reducing the dielectric loss tangent of the polymer film by setting the amount of functional groups to an appropriate amount, it is preferably 10 or less.

In addition, the compound having a functional group may have only one kind of functional group, or two or more kinds of functional groups.

From the viewpoint of adhesiveness with the pattern, the low-molecular-weight compound used as the compound having a functional group preferably has a molecular weight of 50 or more and less than 2,000, more preferably has a molecular weight of 100 or more and less than 1,000, and particularly preferably has a molecular weight of 200 or more and less than 1,000.

In a case where the compound having a functional group is a low-molecular-weight compound, the spread of the compound is narrow, and in order to increase the contact probability between the functional groups, a content of the compound having a functional group is preferably 10% by mass or more with respect to the total mass of the base material.

In addition, from the viewpoint of adhesiveness with the pattern, the high-molecular-weight compound used as the compound having a functional group is preferably a polymer having a weight-average molecular weight of 1,000 or more, more preferably a polymer having a weight-average molecular weight of 2,000 or more, still more preferably a polymer having a weight-average molecular weight of 3,000 or more and 1,000,000 or less, and particularly preferably a polymer having a weight-average molecular weight of 5,000 or more and 200,000 or less.

Furthermore, from the viewpoint of dielectric loss tangent of the base material and adhesiveness with the pattern, it is preferable that the resin and the compound having a functional group described above are compatible with each other. Here, “compatible with each other” means that phase separation is not observed inside the base material.

From the viewpoint of compatibility, dielectric loss tangent of the base material, and adhesiveness with the pattern, a difference between the SP value of the resin, which is determined by Hoy method, and the SP value of the compound having a functional group, which is determined by Hoy method, is preferably 5 MPa^{0.5} or less. The lower limit value thereof is 0 MPa^{0.5}.

The solubility parameter value (SP value) determined by Hoy method is calculated from the molecular structure of the resin by the method described in Polymer Handbook fourth edition. In addition, in a case where the resin is a mixture of a plurality of types of resins, the SP value is obtained by calculating an SP value of each constitutional unit.

The covalent-bondable group is not particularly limited as long as the group is capable of forming a covalent bond with the conductive material or the like, and examples thereof include an epoxy group, an oxctanyl group, an isocyanate group, an acid anhydride group, a carbodiimide group, a N-hydroxy ester group, a glyoxal group, an imidoester group, a halogenated alkyl group, a thiol group, a hydroxy group, a carboxy group, an amino group, an amide group, an aldehyde group, and a sulfonic acid group. Among these, from the viewpoint of adhesiveness with the pattern, the covalent-bondable group is preferably at least one functional group selected from the group consisting of an epoxy group, an oxetanyl group, an N-hydroxy ester group, an isocyanate group, an imide ester group, a halogenated alkyl group, and a thiol group, and particularly preferably an epoxy group.

Examples of the ion-bondable group with the conductive material or the like include a cationic group and an anionic group.

The above-described cationic group is preferably an onium group. Examples of the onium group include an ammonium group, a pyridinium group, a phosphonium group, an oxonium group, a sulfonium group, a selenonium group, and an iodonium group. Among these, from the viewpoint of adhesiveness with the pattern, an ammonium group, a pyridinium group, a phosphonium group, or a sulfonium group is preferable, an ammonium group or a phosphonium group is more preferable, and an ammonium group is particularly preferable.

The anionic group is not particularly limited, and examples thereof include a phenolic hydroxyl group, a carboxy group, —SO₃H, —OSO₃H, —PO₃H, —OPO₃H₂, —CONHSO₂—, and —SO₂NHSO₂—. Among these, a phosphoric acid group, a phosphonic acid group, a phosphinic acid group, a sulfuric acid group, a sulfonic acid group, a sulfinic acid group, or a carboxy group is preferable, a phosphoric acid group or a carboxy group is more preferable, and a carboxy group is still more preferable.

Examples of the hydrogen-bondable group with the conductive material or the like include a group having a hydrogen-bond-donating moiety and a group having a hydrogen-bond-accepting moiety.

It is sufficient that the hydrogen-bond-donating moiety has a structure having an active hydrogen atom capable of hydrogen bonding, and a structure represented by X—H is preferable.

X represents a heteroatom, and is preferably a nitrogen atom or an oxygen atom.

From the viewpoint of adhesiveness with the pattern, as the above-described hydrogen-bond-donating moiety, at least one structure selected from the group consisting of a hydroxy group, a carboxy group, a primary amide group, a secondary amide group, a primary amino group, a secondary amino group, a primary sulfonamide group, a secondary sulfonamide group, an imide group, a urea bond, and a urethane bond is preferable; at least one structure selected from the group consisting of a hydroxy group, a carboxy group, a primary amide group, a secondary amide group, a primary sulfonamide group, a secondary sulfonamide group, a maleimide group, a urea bond, and a urethane bond is more preferable; at least one structure selected from the group consisting of a hydroxy group, a carboxy group, a primary amide group, a secondary amide group, a primary sulfonamide group, a secondary sulfonamide group, and a maleimide group is still more preferable; and at least one structure selected from the group consisting of a hydroxy group and a secondary amide group is particularly preferable.

The above-described hydrogen-bond-accepting moiety may be a structure containing an atom with an unshared electron pair, and a structure containing an oxygen atom with an unshared electron pair is preferable; at least one structure selected from the group consisting of a carbonyl group (including a carbonyl structure such as a carboxy group, an amide group, an imide group, a urea bond, and a urethane bond) and a sulfonyl group (including a sulfonyl structure such as a sulfonamide group) is more preferable; and a carbonyl group (including a carbonyl structure such as a carboxy group, an amide group, an imide group, a urea bond, and a urethane bond) is particularly preferable.

As the hydrogen-bondable group, a group having both the hydrogen-bond-donating moiety and the hydrogen-bond-accepting moiety described above is preferable; it is preferable to have a carboxy group, an amide group, an imide group, a urea bond, a urethane bond, or a sulfonamide group; and it is more preferable to have a carboxy group, an amide group, an imide group, or a sulfonamide group.

It is sufficient that the dipole-interactable group with the conductive material or the like is a group having a polarized structure other than the above-described structure represented by X—H (X represents a heteroatom, for example, a nitrogen atom or an oxygen atom) in the hydrogen-bondable group, and suitable examples thereof include a group in which atoms with different electronegativities are bonded to each other.

As a combination of the atoms with different electronegativities, a combination of at least one atom selected from the group consisting of an oxygen atom, a nitrogen atom, a sulfur atom, and a halogen atom, and a carbon atom is preferable; and a combination of at least one atom selected from the group consisting of an oxygen atom, a nitrogen atom, and a sulfur atom, and a carbon atom is more preferable.

Among these, from the viewpoint of adhesiveness with the pattern, a combination of a nitrogen atom and a carbon atom or a combination of a carbon atom, a nitrogen atom, an oxygen atom, and a sulfur atom is preferable, and specifically, a cyano group, a cyanuric group, or a sulfonic acid amide group is more preferable.

Preferred examples of the compound having a curing reactive group with the conductive material or the like include the following curable compound.

The curable compound is a compound which is cured by irradiation with heat or light (for example, visible light, ultraviolet rays, near-infrared rays, far-infrared rays, electron beam, or the like). Examples of such a curable compound include an epoxy compound, a cyanate ester compound, a vinyl compound, a silicone compound, an oxazine compound, a maleimide compound, an allyl compound, an acrylic compound, a methacrylic compound, and a urethane compound. These may be used alone or in combination of two or more thereof. Among these, from the viewpoint of characteristics such as compatibility with the resin and heat resistance, at least one selected from the group consisting of an epoxy compound, a cyanate ester compound, a vinyl compound, a silicone compound, an oxazine compound, a maleimide compound, and an allyl compound is preferable; and at least one selected from the group consisting of an epoxy compound, a cyanate ester compound, a vinyl compound, an allyl compound, and a silicone compound is more preferable.

From the viewpoint of adhesiveness with the pattern, a content of the compound having a functional group with respect to the total mass of the base material is preferably 0.01% by mass to 10% by mass, more preferably 0.03% by mass to 5% by mass, and still more preferably 0.05% by mass to 3% by mass.

### (Filler)

The base material may contain at least one filler. The filler may be an organic filler or an inorganic filler.

Examples of the organic filler include particles of a liquid crystal polymer, polyolefin, a fluorine-based polymer, and the like.

Examples of the inorganic filler include particles of silica, alumina, titania, zirconia, kaolin, calcined kaolin, talc, mica, sodium carbonate, calcium carbonate, aluminum hydroxide, magnesium hydroxide, zinc oxide, and the like.

From the viewpoint of reducing the thermal expansion coefficient, it is preferable that the base material contains silica particles.

In a case where the base material has a multilayer structure, from the viewpoint of improving smoothness of the pattern formed on the surface of the base material, it is preferable that the filler is contained in a layer other than the layer having the surface on which the pattern is formed. For example, in a case where the base material has a three-layer structure of a first layer, a second layer, and a third layer and the pattern is formed on the first layer, it is preferable that the second layer or the third layer contains the filler.

From the viewpoint of thermal expansion coefficient and adhesiveness with the pattern, an average particle diameter of the filler is preferably 5 nm to 20 μm, more preferably 10 nm to 10 μm, still more preferably 20 nm to 1 μm, and particularly preferably 25 nm to 500 nm.

In the present disclosure, the average particle diameter of the filler is obtained by arithmetically averaging particle diameters of 50 particles randomly selected from an image of a scanning electron microscope (SEM).

From the viewpoint of thermal expansion coefficient of the base material and adhesiveness with the pattern, a content of the filler with respect to the total mass of the base material is preferably 10% by mass to 40% by mass, more preferably 15% by mass to 35% by mass, and still more preferably 20% by mass to 30% by mass.

In a case where the base material has a multilayer structure, from the viewpoint of reducing the thermal expansion coefficient, the content of the filler with respect to the total mass of the layer containing the filler is preferably 20% by mass to 70% by mass, more preferably 30% by mass to 65% by mass, and still more preferably 40% by mass to 60% by mass.

### (Additive)

The base material may contain various additives, and examples thereof include a polymerization initiator, a dispersant, a surfactant, a crosslinking agent, and an antioxidant.

In addition, as the base material, a woven fabric such as a glass cloth, a nonwoven fabric, or the like may be used by being impregnated with the above-described resin. Furthermore, a layer may be formed on at least one surface of the glass cloth or the like, impregnated with the above-described resin, using the above-described material such as the resin to be a base material having a multilayer structure.

A thickness of the base material is not particularly limited, and from the viewpoint of handleability, it is preferably 5 μm to 200 μm, more preferably 10 μm to 180 μm, and still more preferably 15 μm to 150 μm.

As the base material, a base material which is produced by a known method in the related art may be used, or a commercially available base material may be used. A method for producing the base material will be described with reference to Examples.

### [Metamaterial]

The metamaterial according to the present disclosure includes a base material for a metamaterial and a pattern provided on a surface of the base material for a metamaterial, the surface having a surface roughness Ra of 300 nm or less, in which the pattern is composed of at least one of a conductive material or a material which transits from an insulator to a conductor. The base material for a metamaterial is described above, and thus the description thereof will be omitted here.

### (Pattern)

The pattern is composed of at least one of a conductive material or a material which transits from an insulator to a conductor.

The conductive material preferably contains a metal, and more preferably is one or more selected from the group consisting of gold, silver, platinum, copper, and aluminum. Among these, from the viewpoint of smoothness of the pattern, crack suppressibility, and the like, at least one of gold or copper is particularly preferable.

A content of the metal with respect to the total mass of the conductive material is not particularly limited, and may be 80% by mass or more, 90% by mass or more, or 100% by mass.

As the material which transits from an insulator to a conductor, a material which transits from an insulator to a conductor by heating, light irradiation, or applying a voltage can be used.

The material which transits from an insulator to a conductor is preferably one or more selected from the group consisting of a phase change material, a semiconductor, a conductive oxide, and a carbon material.

In the present disclosure, the phase change material means a material which causes a phase change between an amorphous phase and a crystalline phase by Joule heat due to an electric pulse.

Examples of the phase change material include vanadium oxide, an antimony tellurium (SbTe) alloy, a germanium tellurium (GeTe) alloy, a germanium antimony tellurium (GeSbTe) alloy, an indium antimony tellurium (InSbTe) alloy, and a silver indium antimony tellurium (AgInSbTe) alloy. Among these, from the viewpoint of easily controlling a temperature and a voltage at which the insulator is transited to the conductor, smoothness of the pattern, crack suppressibility, and the like, vanadium oxide or a GeSbTe alloy is preferable.

Examples of the semiconductor include a p-type x-conjugated polymer, a condensed polycyclic compound, a triarylamine compound, a hetero 5-membered ring compound, a phthalocyanine compound, and a porphyrin compound.

Examples of the conductive oxide include indium tin oxide (ITO), indium zinc oxide (IZO), zinc oxide (ZnO), and indium gallium zinc oxide (IGZO).

Examples of the carbon material include carbon nanotube and graphene.

The pattern may include a plurality of structural bodies. The pattern may include two or more structural bodies having different shapes, sizes, and the like.

A shape of the structural body is not particularly limited, but is preferably a shape capable of inducing a dielectric or magnetic response change by generating a charge bias, a current, or the like in the structural body or between adjacent structural bodies due to an interaction between the electric field, the magnetic field, or the like of an electromagnetic wave in a terahertz band, which is incident on the metamaterial.

The shape of the structural body is not particularly limited, and examples thereof include a C-shape, a U-shape, a double ring shape, a V-shape, an L-shape, a lattice shape, a spiral shape, a square shape, a circular shape, and a cross shape in an in-plane direction of the base material. The structural body is composed of the conductive material or the material which transits from an insulator to a conductor.

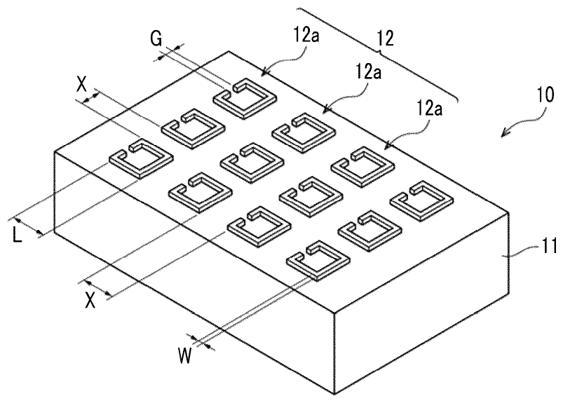

The structural body is preferably a split-ring resonator. The split-ring resonator means a structural body having a C-shape or a U-shape, and has a gap indicated by a reference numeral G in FIG. 1.

A size of the structural body is not particularly limited, but is preferably equal to or less than a wavelength size of the incident electromagnetic wave in the terahertz band.

In the present disclosure, the maximum length of the structural body means a length which is longest in a case where a straight line is drawn from one end to the other end of the structural body in the in-plane direction of the base material.

From the viewpoint of smoothness of the pattern, a width of the structural body is preferably 3 μm to 25 μm.

In addition, in a case where the structural body is a split-ring resonator, from the viewpoint of smoothness of the pattern, the gap is preferably 1 μm to 15 μm.

A distance between the structural bodies is preferably appropriately changed according to the shape, size, and the like of the structural body, and for example, it can be set to 30 μm to 400 μm.

A disposition position of the structural body on the surface of the base material is not particularly limited, and is preferably a disposition in which the structural body resonates with the electromagnetic wave in the terahertz band.

In addition, the structural body may be disposed on the surface of the base material, in which a periodic structure is formed such that the amount of phase shift of the electromagnetic wave in the terahertz band is continuously increased or decreased as the region goes from the center of the surface of the base material to the outer side. Examples of the above-described periodic structure include a structure in which structural bodies having different diameters are arranged in a concentric circle. A change width of the diameter of the structural bodies arranged in a concentric circle can be set to 10 μm to 200 μm.

In a case where the base material contains the compound having a functional group, the pattern preferably has a functional group such as an amino group and a hydroxy group.

In a case where the compound having a functional group has a covalent-bondable group, the pattern preferably has a functional group such as an amino group, a hydroxy group, an epoxy group, an oxetanyl group, an N-hydroxy ester group, and an imide ester group.

In a case where the compound having a functional group has an ion-bondable group, the pattern preferably has a functional group such as a carboxy group, a sulfo group, a phosphoric acid group, a tertiary amino group, a pyridyl group, and a piperidyl group.

In a case where the compound having a functional group has a hydrogen-bondable group, the pattern preferably has a group having a hydrogen-bond-donating moiety or a group having a hydrogen-bond-accepting moiety.

In a case where the compound having a functional group has a dipole-interactable group, the pattern preferably has a dipole-interactable group.

The above-described functional group may be introduced into the surface of the base material on the side in contact with the base material, by performing a chemical treatment or the like.

From the viewpoint of cost reduction, a thickness of the pattern is preferably less than 5 μm, more preferably 0.05 μm to 4 μm, still more preferably 0.1 μm to 3 μm, and particularly preferably 0.3 μm to 1 μm.

A method of forming the pattern is not particularly limited, and for example, the pattern can be formed by forming a sputtered film on the surface of the base material by a sputtering method, forming a resist pattern on a surface of the sputtered film, etching and removing the sputtered film not covered with the resist pattern, and then removing the resist pattern.

The method of forming the pattern is not limited to the above-described methods, and the thin film may be formed by a vapor deposition method instead of the sputtering method.

An embodiment of the metamaterial will be described with reference to FIG. 1. However, the metamaterial is not limited thereto.

As shown in FIG. 1, a metamaterial 10 includes a base material 11 and a pattern 12 provided on a surface of the base material 11.

In FIG. 1, the pattern 12 includes a plurality of structural bodies 12a. In FIG. 1, the maximum length of the structural body 12a is indicated by a reference numeral L, the width of the structural body 12a is indicated by a reference numeral W, the gap of the structural body 12a is indicated by a reference numeral G, and the distance between the structural bodies is indicated by a reference numeral X.

The applications of the metamaterial according to the present disclosure are not particularly limited, and examples thereof include a flat lens, a diffraction grating, a wavelength filter, a polarizer, a sensor, a reflector, and a flat prism.

In addition, the use environment thereof is not particularly limited, and the metamaterial may be mounted on an electronic apparatus or the like or may be installed outdoors as a wavelength filter.

### [Laminate]

The laminate according to the present disclosure includes the above-described metamaterial and an organic film provided on a surface of the metamaterial on the pattern side. The organic film may have a monolayer structure or a multilayer structure.

From the viewpoint of suppressing occurrence of corrosion in the pattern, a moisture permeability of the organic film in an environment of a temperature of 40° C. and a relative humidity of 90% is preferably 3,000 g/(m²·24 hours) or less, more preferably 2,000 g/(m²·24 hours) or less, still more preferably 1,500 g/(m²·24 hours) or less, and particularly preferably 1,000 g/(m²·24 hours) or less.

The organic film can contain a resin. The resin is as described above, and the description thereof will be omitted here.

A content of the resin with respect to the total mass of the organic film is not particularly limited, but is preferably 10% by mass to 90% by mass, more preferably 20% by mass to 80% by mass, and still more preferably 30% by mass to 70% by mass.

The organic film may contain an ultraviolet absorber. As a result, it is possible to improve weather fastness of the laminate and to improve suitability of the laminate for applications of being installed outdoors.

Examples of the ultraviolet absorber include a conjugated diene compound, an aminodiene compound, a salicylate compound, a benzophenone compound, a benzotriazole compound, an acrylonitrile compound, a hydroxyphenyltriazine compound, an indole compound, and a triazine compound.

In addition, in a case where the organic film has a multilayer structure, the organic film preferably includes a layer containing the ultraviolet absorber.

From the viewpoint of weather fastness and prevention of bleed out, a content of the ultraviolet absorber with respect to the total mass of the organic film is preferably 0.01% by mass to 30% by mass, more preferably 0.1% by mass to 10% by mass, and still more preferably 0.5% by mass to 5% by mass.

The organic film may contain the above-described additives.

A thickness of the organic film is not particularly limited, but from the viewpoint that transmission characteristics of the electromagnetic wave are not impaired, it is preferably 20 μm or less, more preferably 10 μm or less, and still more preferably 5 μm or less. The lower limit thereof is not particularly limited, but is 0.5 μm or more in many cases.

A method for manufacturing the laminate is not particularly limited, and the laminate may be formed by adding the above-described resin and the like to a solvent as necessary to form a composition, and applying the composition onto the surface of the metamaterial and drying the composition. In addition, the laminate may be manufactured by applying the composition onto a temporary support and drying the composition to form an organic film, producing a transfer sheet, and transferring the organic film from the transfer sheet to a surface of the metamaterial.

### EXAMPLES

Hereinafter, the above-described embodiment will be specifically described with reference to Examples, but the above-described embodiment is not limited to Examples. Unless otherwise specified, the unit of numerical values in Table 1 is part by mass. In addition, the content in Table 1 indicates a content as the solid content.

### Synthesis Example 1: Synthesis of Liquid Crystal Polyester LC-A

A reactor including a stirrer, a torque meter, a nitrogen gas introduction pipe, a thermometer, and a reflux condenser was prepared.

940.9 g (5.0 mol) of 6-hydroxy-2-naphthoic acid, 377.9 g (2.5 mol) of 4-hydroxyacetaminophen, 415.3 g (2.5 mol) of isophthalic acid, and 867.8 g (8.4 mol) of acetic acid anhydride were charged into the above-described reactor, the gas in the reactor was replaced with nitrogen gas, and the mixture was heated from room temperature (23° C.) to 143° C. over 60 minutes while being stirred under a nitrogen gas stream and was refluxed at 143° C. for 1 hour.

Thereafter, the mixture was heated from 150° C. to 300° C. over 5 hours while distilling off by-product acetic acid and unreacted acetic acid anhydride and maintained at 300° C. for 30 minutes, and the resultant was taken out from the reactor and cooled to room temperature. The obtained solid matter was crushed with a crusher, thereby obtaining powdery liquid crystal polyester A1.

The liquid crystal polyester A1 obtained above was heated from room temperature to 160° C. over 2 hours and 20 minutes in a nitrogen atmosphere, further heated from 160° C. to 180° C. over 3 hours and 20 minutes, maintained at 180° C. for 5 hours to carry out solid phase polymerization, cooled, and crushed with a crusher, thereby obtaining powdery liquid crystal polyester A2.

The liquid crystal polyester A2 was heated from room temperature (23° C.) to 180° C. over 1 hour and 20 minutes in a nitrogen atmosphere, further heated from 180° C. to 240° C. over 5 hours, maintained at 240° C. for 5 hours to carry out solid phase polymerization, and cooled, thereby obtaining powdery liquid crystal polyester LC-A.

### Synthesis Example 2: Synthesis of Liquid Crystal Polyester LC-C

248.6 g (1.8 mol) of 4-hydroxybenzoic acid, 478.6 g (3.1 mol) of 4-hydroxyacetanilide, 681.1 g (4.1 mol) of isophthalic acid, 110.1 g (1.0 mol) of hydroquinone, and 806.5 g (7.9 mol) of acetic acid anhydride were charged into the above-described reactor, the gas in the reactor was replaced with nitrogen gas, and the mixture was heated from room temperature (23° C.) to 150° C. over 15 minutes while being stirred under a nitrogen gas stream and was refluxed at 150° C. for 3 hours.

Thereafter, the mixture was heated from 150° C. to 300° C. over 5 hours while distilling off by-product acetic acid and unreacted acetic acid anhydride, and the resultant was taken out from the reactor and cooled to room temperature. The obtained solid matter was crushed with a crusher, thereby obtaining powdery liquid crystal polyester C1.

The liquid crystal polyester C1 was maintained at 290° C. for 3 hours in a nitrogen atmosphere to carry out solid phase polymerization, cooled, and crushed with a crusher, thereby obtaining powdery liquid crystal polyester LC-C.

(Preparation Example 1: preparation of filler F-1)

1034.99 g (5.5 mol) of 2-hydroxy-6-naphthoic acid, 378.33 g (1.75 mol) of 2,6-naphthalenedicarboxylic acid, 83.07 g (0.5 mol) of terephthalic acid, 272.52 g (2.475 mol) of hydroquinone (0.225 mol excess with respect to the total molar amount of the 2,6-naphthalenedicarboxylic acid and the terephthalic acid), 1226.87 g (12 mol) of acetic acid anhydride, and 0.17 g of 1-methylimidazole as a catalyst were charged into the above-described reactor. After the gas in the reactor was replaced with nitrogen gas, the mixture was heated from room temperature to 145° C. over 15 minutes while being stirred in a nitrogen gas stream and was refluxed at 145° C. for 1 hour.

Next, the mixture was heated from 145° C. to 310° C. over 3 hours 30 minutes while distilling off by-product acetic acid and unreacted acetic acid anhydride and maintained at 310° C. for 3 hours, and solid liquid crystal polyester LC-B was taken out and cooled to room temperature. The flow start temperature of the liquid crystal polyester LC-B was 265° C.

Using a jet mill (manufactured by KURIMOTO Ltd., KJ-200), the liquid crystal polyester LC-B was crushed to obtain a filler F-1. An average particle diameter of the filler F-1 was 9 μm.

### Example 1

The liquid crystal polyester shown in Table 1 was added to N-methylpyrrolidone, and the mixture was stirred at 140° C. for 4 hours in a nitrogen atmosphere to form a solution, and allowed to pass through a sintered fiber metal filter having a nominal pore diameter of 10 μm and then allowed to pass through a sintered fiber metal filter having the same nominal pore diameter of 10 μm. Thereafter, the filler shown in Table 1 was added thereto to obtain a composition A.

In addition, the liquid crystal polyester shown in Table 1 was added to N-methylpyrrolidone, and the mixture was stirred at 140° C. for 4 hours in a nitrogen atmosphere to form a solution, and allowed to pass through a sintered fiber metal filter having a nominal pore diameter of 10 μm and then allowed to pass through a sintered fiber metal filter having the same nominal pore diameter of 10 μm to obtain a composition B.

The contents of the liquid crystal polyester and the filler in the composition A and the composition B are shown in Table 1. The concentration of solid contents of the liquid crystal polyester in the composition A and the composition B was set to 10% by mass.

The composition A and the composition B were fed to a casting die equipped with a multi-manifold for co-casting, and cast on an aluminum foil having a thickness of 50 μm as a support to produce a base material having a three-layer structure of a layer formed of the composition B and having a thickness of 25 μm (referred to as a first layer in Table 1), a layer formed the composition A and having a thickness of 30 μm (referred to as a second layer in Table 1), and a layer formed of the composition B and having a thickness of 5 μm (referred to as a third layer in Table 1). The aluminum foil was in contact with the third layer.

The above-described base material was dried at 40° C. for 4 hours to remove the solvent from the base material, and the base material was further heated from room temperature (25° C.) to 290° C. at 1° C./min under a nitrogen atmosphere to perform a heat treatment of maintaining the temperature for 2 hours, and the base material was cooled to room temperature, and then the aluminum foil was peeled off and further heated at 200° C. for 1 minute.

In a case where a dielectric loss tangent of the base material produced as described above was measured by the following terahertz time-domain spectroscopy (THz-TDS), it was 0.003.

First, the base material was cut into a test piece having a size of 100 mm×100 mm.

Next, an optical system for transmission-type terahertz spectroscopy was produced, and a dielectric loss tangent of the test piece was measured from a change in time waveform of the electric field (frequency: 1 THz) before and after insertion of the test piece in an environment of a temperature of 25° C. and a humidity of 10% RH.

In a case where the base material piece was enclosed in a measuring pan, and using a differential scanning calorimeter (DSC6200) manufactured by Seiko Instruments Inc., a glass transition temperature was obtained from a thermogram obtained by raising the temperature at a rate of 20° C./min, in which the baseline and the intersection temperature of the tangent line at the inflection point were obtained, it was 184° C.

A sputtered copper film having a thickness of 0.5 μm was formed on the surface of the first layer of the above-described base material.

A resist pattern was formed on the surface of the sputtered film, the sputtered film not covered with the resist pattern was etched and removed, and then the resist pattern was removed to form a pattern including a plurality of C-shaped split-ring resonators, thereby obtaining a metamaterial.

The split-ring resonator had a width of 15 μm, a maximum length of 92 μm, a C-shape in a shape viewed from a normal direction of the base material, a gap of 10 μm, and a distance between the split-ring resonators of 200 μm.

A composition C containing 98.0 parts by mass of a cycloolefin polymer P-1 (manufactured by JSR Corporation, ARTON (registered trademark) F3500), 2 parts by mass of an ultraviolet absorber having the following structure, and 400 parts by mass of dichloromethane was applied onto the surface of the metamaterial produced as described above on the pattern side, dried, and formed into an organic film having a thickness of 10 μm, thereby obtaining a laminate.

In a case where a moisture permeability was measured under conditions of a temperature of 40° C., a relative humidity of 90%, and 24 hours of standing, in conformity with the method of JIS Z 0208 (1976), it was 360 g/(m²·24 hours).

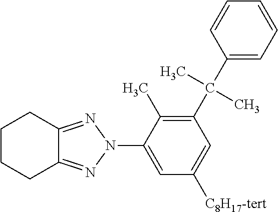

A cross-sectional sample of the laminate produced as described above was cut out using a microtome, and a curve of an interface shape of the base material for a metamaterial, the pattern, and the organic film and an average line of the curve of the interface shape were created.

In a case where a surface roughness Ra was obtained from the interface shape curve on the pattern side (first layer side) of the base material for a metamaterial and the average line thereof, it was 3 nm. For the measurement of the surface roughness Ra, a non-contact surface and cross-sectional shape measurement system VertScan (manufactured by Mitsubishi Chemical System Co., Ltd.) was used, and the surface roughness Ra was measured in a square range of 465.48 μm in length and 620.64 μm in width.

### Example 2

A metamaterial and a laminate were produced in the same manner as in Example 1, except that the filler F-1 was changed to a filler F-2. The details of the filler F-2 are as follows.

In a case where a glass transition temperature of the base material was measured by the same method as in Example 1, it was 184° C. In a case where a surface roughness Ra of the base material was measured by the same method as in Example 1, it was 1 nm. In a case where a dielectric loss tangent of the base materials was measured by the same method as in Example 1, it was 0.002.
Filler F-2: copolymer particles of ethylene tetrafluoride and perfluoroalkoxy ethylene (PFA) (melting point: 280° C., average particle diameter: 0.2 μm to 0.5 μm, dielectric loss tangent: 0.001)

### Example 3

The liquid crystal polyester shown in Table 1 was added to N-methylpyrrolidone, and the mixture was stirred at 140° C. for 4 hours in a nitrogen atmosphere to form a solution, and allowed to pass through a sintered fiber metal filter having a nominal pore diameter of 5 μm and allowed to pass through a sintered fiber metal filter having the same nominal pore diameter of 5 μm.

A compound M-1 having a functional group (aminophenol-type epoxy resin, jER630LSD, manufactured by Mitsubishi Chemical Corporation, having an epoxy group which could be covalently bonded to the liquid crystal polyester and was a hydrogen-bondable group with glass cloth) was added to the liquid crystal polyester after passing through the filter, and the mixture was stirred at 25° C. for 30 minutes to obtain a composition D.

In addition, the liquid crystal polyester shown in Table 1 was added to N-methylpyrrolidone, and the mixture was stirred at 140° C. for 4 hours in a nitrogen atmosphere, and allowed to pass through a sintered fiber metal filter having a nominal pore diameter of 5 μm and then allowed to pass through a sintered fiber metal filter having the same nominal pore diameter of 5 μm to obtain a composition E.

The contents of the liquid crystal polyester and the compound M-1 having a functional group in the composition D and the composition E are shown in Table 1. The concentration of solid contents of the composition D and the composition E was adjusted such that the solution viscosity at room temperature (23° C.) was 0.3 Pa·s.

A low dielectric property glass cloth (NE glass, manufactured by Nittobo Co., Ltd.) was impregnated with the composition D, and the solvent was evaporated at 160° C. to obtain a glass cloth base material having a thickness of 60 μm.

Subsequently, one surface of the glass cloth base material was coated with the composition E using a reverse gravure coater, and dried at 160° C. Further, heating was performed in a nitrogen atmosphere from room temperature to 290° C. at 1° C./min, and a heat treatment was performed at the temperature for 2 hours to obtain a base material. A thickness of the first layer formed of the composition E was 20 μm.

A metamaterial and a laminate were produced in the same manner as in Example 1, except that the base material was changed to the base material produced by the above-described method, and the pattern was formed on the surface of the layer formed of the composition E.

In a case where a glass transition temperature of the base material was measured by the same method as in Example 1, it was 210° C. In a case where a surface roughness Ra of the base material was measured by the same method as in Example 1, it was 6 nm. In a case where a dielectric loss tangent of the base materials was measured by the same method as in Example 1, it was 0.005.

### Example 4

A liquid crystal polyester LC-D (manufactured by Polyplastics Co., Ltd., VECTRA (registered trademark) A950) was pelletized under a nitrogen atmosphere using a biaxial extruder.

The obtained pellets were supplied into a cylinder through the same supply port of the biaxial extruder having a screw diameter of 50 mm, and heated and kneaded at 340° C. to 350° C. to obtain a kneaded material.

Subsequently, the kneaded material was fed to a T-die, and a film-like kneaded material in a molten state was discharged and solidified on a chill roll. The obtained film was stripped from the chill roll, and stretched by tenter to adjust anisotropy (MD/TD) of storage elastic modulus to 2 or less, thereby obtaining a film having a thickness of 55 μm.

The composition B was applied onto both surfaces of the above-described film using a reverse gravure coater, and a heat treatment was performed in a nitrogen atmosphere at room temperature (25° C.) to 270° C., and the temperature was maintained for 2 hours to obtain a base material.

The base material had a three-layer structure of a layer formed of the composition B and having a thickness of 15 μm (referred to as a first layer in Table 1), a layer formed of the above-described kneaded material and having a thickness of 55 μm (referred to as a second layer in Table 1), and a layer formed of the composition B and having a thickness of 5 μm (referred to as a third layer in Table 1).

A metamaterial and a laminate were produced in the same manner as in Example 1, except that the base material was changed to the base material produced by the above-described method.

In a case where a glass transition temperature of the base material was measured by the same method as in Example 1, it was 184° C. and 210° C. In a case where a surface roughness Ra of the base material was measured by the same method as in Example 1, it was 1 nm. In a case where a dielectric loss tangent of the base materials was measured by the same method as in Example 1, it was 0.002.

### Example 5

A cycloolefin polymer P-1 (manufactured by JSR Corporation, ARTON (registered trademark) F3500) was added to dichloromethane, stirred at 60° C. for 30 minutes to be liquefied, and passed through a sintered fiber metal filter having a nominal pore diameter of 10 μm and then passed through a sintered fiber metal filter having the same nominal pore diameter of 10 μm, thereby obtaining a composition F.

A compound M-1 having a functional group was added to the composition F, and the mixture was stirred at 25° C. for 30 minutes to obtain a composition G

The contents of the cycloolefin polymer P-1 and the compound M-1 having a functional group in the composition F and the composition G are shown in Table 1.

The composition F and the composition G were fed to a casting die equipped with a multi-manifold for co-casting, and cast on a stainless band as a support to produce a base material having a two-layer structure of a layer formed of the composition F and having a thickness of 60 μm (referred to as a first layer in Table 1) and a layer formed of the composition G and having a thickness of 60 μm (referred to as a second layer in Table 1).

The stainless band was in contact with the second layer.

The base material was peeled off from the support in the MD direction while applying a 3% draw, and both ends were gripped with a tenter clip and dried at 170° C. for 3 minutes to be stretched by 5% in the TD direction at a stage where the residual solvent amount was 10% by mass by hot air-drying the base material.

A metamaterial and a laminate were produced in the same manner as in Example 1, except that the base material was changed to the base material produced by the above-described method, and the pattern was formed on the surface of the first layer.

In a case where a glass transition temperature of the base material was measured by the same method as in Example 1, it was 165° C. In a case where a surface roughness Ra of the base material was measured by the same method as in Example 1, it was 1 nm. In a case where a dielectric loss tangent of the base materials was measured by the same method as in Example 1, it was 0.002.

### Comparative Example 1

A metamaterial and a laminate were produced in the same manner as in Example 1, except that the base material was changed to a cycloolefin polymer film having a thickness of 100 μm (manufactured by ZEON CORPORATION, ZEONOR (registered trademark) ZF-14, described as PF-1 in Table 1).

In a case where a glass transition temperature of the base material was measured by the same method as in Example 1, it was 136° C. In a case where a surface roughness Ra of the base material was measured by the same method as in Example 1, it was 20 nm. In a case where a dielectric loss tangent of the base materials was measured by the same method as in Example 1, it was less than 0.001.

A metamaterial and a laminate were produced in the same manner as in Example 1, except that the base material was changed to a liquid crystal polymer film having a thickness of 50 μm (manufactured by Kuraray Co., Ltd., VECTRA (registered trademark) CTQ, described as PF-2 in Table 1).

In a case where a glass transition temperature of the base material was measured by the same method as in Example 1, it was 214° C. In a case where a surface roughness Ra of the base material was measured by the same method as in Example 1, it was 304 nm. In a case where a dielectric loss tangent of the base materials was measured by the same method as in Example 1, it was 0.002.

### <<Evaluation of Pattern Smoothness>>

A cross-sectional sample of the laminate produced in Examples and Comparative Examples was cut out using a microtome, and a curve of the interface shape of the pattern and an average line of the curve of the interface shape were created.

The surface roughness Ra was obtained from the interface shape curve on a side of the pattern opposite to the base material for a metamaterial and the average line thereof, and is shown in Table 2.

For the measurement of the surface roughness Ra, a non-contact surface and cross-sectional shape measurement system VertScan (manufactured by Mitsubishi Chemical System Co., Ltd.) was used, and the surface roughness Ra was measured in a square range of 465.48 μm in length and 620.64 μm in width.

TABLE 1

| | First layer | | | | | | | Second layer | | | |
|---|---|---|---|---|---|---|---|---|---|---|---|
| | Liquid crystal | | Cycloolefin | | Compound having | | | Liquid crystal | | Cycloolefin | |
| | polyester | | polymer | | functional group | | | polyester | | polymer | |
| | | Content | | Content | | Content | | | Content | | Content |
| | | (part by | | (part by | | (part by | Thickness | | (part by | | (part by |
| | Type | mass) | Type | mass) | Type | mass) | (μm) | Type | mass) | Type | mass) |
| Example 1 | LC-A | 100 | — | — | — | — | 25 | LC-A | 50 | — | — |
| Example 2 | LC-A | 100 | — | — | — | — | 25 | LC-A | 50 | — | — |
| Example 3 | LC-C | 100 | — | — | — | — | 20 | LC-C | 95.5 | — | — |
| Example 4 | LC-A | 100 | — | — | — | — | 15 | LC-D | 100 | — | — |
| Example 5 | — | — | P-1 | 99 | M-1 | 1 | 60 | — | — | P-1 | 100 |
| Comparative | — | — | PF-1 | 100 | — | — | 100 | — | — | — | — |
| Example 1 | | | | | | | | | | | |
| Comparative | — | — | PF-2 | 100 | — | — | 50 | — | — | — | — |
| Example 2 | | | | | | | | | | | |

| | Second layer | | | | | Third layer | | |
|---|---|---|---|---|---|---|---|---|
| | Compound having | | | | | Liquid crystal | | |
| | functional group | | Filler | | | polyester | | |
| | | Content | | Content | | | Content | |
| | | (part by | | (part by | Thickness | | (part by | Thickness |
| | Type | mass) | Type | mass) | (μm) | Type | mass) | (μm) |
| Example 1 | — | — | F-1 | 50 | 30 | LC-A | 100 | 5 |
| Example 2 | — | — | F-2 | 50 | 30 | LC-A | 100 | 5 |
| Example 3 | M-1 | 0.5 | — | — | 60 | — | — | — |
| Example 4 | — | — | — | — | 55 | LC-A | 100 | 10 |
| Example 5 | — | — | — | — | 60 | — | — | — |
| Comparative | — | — | — | — | — | — | — | — |
| Example 1 | | | | | | | | |
| Comparative | — | — | — | — | — | — | — | — |
| Example 2 | | | | | | | | |

TABLE 2

| | | | | Evaluation |
|---|---|---|---|---|
| | | | | of pattern |
| | | | | smoothness |
| | Base material | | | Surface |
| | Dielectric | Glass transition | Surface | roughness |
| | loss | temperature | roughness Ra | Ra of pattern |
| | tangent | (° C.) | (nm) | (nm) |
| Example 1 | 0.003 | 184 | 3 | 3 |
| Example 2 | 0.002 | 184 | 1 | 1 |
| Example 3 | 0.005 | 210 | 6 | 6 |
| Example 4 | 0.002 | 184, 210 | 1 | 1 |
| Example 5 | 0.002 | 165 | 1 | 1 |
| Comparative | <0.001 | 136 | 20 | 35 |
| Example 1 | | | | |
| Comparative | 0.002 | 214 | 304 | 450 |
| Example 2 | | | | |

From Table 2, it was found that the heat resistance and the smoothness of the metamaterial and the laminate obtained in Examples were excellent as compared with the metamaterial and the laminate obtained in Comparative Examples, and the smoothness of the pattern to be formed was excellent.

The disclosure of JP2022-030210 filed on Feb. 28, 2022 is incorporated in the present specification by reference. All documents, patent applications, and technical standards described in the present specification are incorporated herein by reference to the same extent as in a case of being specifically and individually noted that individual documents, patent applications, and technical standards are incorporated herein by reference.

What is claimed is:

1. A base material for a metamaterial,
wherein a glass transition temperature is 160° C. or higher, and
a surface roughness Ra of at least one surface is 300 nm or less.

2. The base material for a metamaterial according to claim 1,
wherein a dielectric loss tangent is 0.01 or less.

3. The base material for a metamaterial according to claim 1,
wherein the base material for a metamaterial contains at least one selected from the group consisting of a fluorine-based polymer and a liquid crystal polymer.

4. A metamaterial comprising:
the base material for a metamaterial according to claim 1; and
a pattern provided on a surface of the base material for a metamaterial, the surface having a surface roughness Ra of 300 nm or less,
wherein the pattern is composed of at least one of a conductive material or a material which transits from an insulator to a conductor.

5. The metamaterial according to claim 4,
wherein a thickness of the pattern is less than 5 μm.

6. The metamaterial according to claim 4,
wherein the pattern includes a plurality of structural bodies, and
the structural bodies are a split-ring resonator.

7. The metamaterial according to claim 4,
wherein the pattern is composed of the conductive material, and
the conductive material includes a metal.

8. A laminate comprising:
the metamaterial according to claim 4; and
an organic film provided on a surface of the metamaterial on a pattern side.

9. The laminate according to claim 8,
wherein a moisture permeability of the organic film in an environment of a temperature of 40° C. and a relative humidity of 90% is 3.000 g/(m²·24 hours) or less.

10. The laminate according to claim 8,
wherein the organic film contains an ultraviolet absorber.
